(19) United States
(12) Patent Application Publication
(10) Pub. No.: US 2015/0311099 A1
(43) Pub. Date: Oct. 29, 2015

(54) Wafer Stage Having Function of Anti-Collision

(71) Applicants: SHANGHAI MICRO ELECTRONICS EQUIPMENT CO., LTD., Shanghai (CN); TSINGHUA UNIVERSITY, Beijing (CN)

(72) Inventors: Yu Zhu, Haidian District Beijing (CN); Ming Zhang, Haidian District Beijing (CN); Zhao Liu, Haidian District Beijing (CN); Kaiming Yang, Haidian District Beijing (CN); Dengfeng Xu, Haidian District Beijing (CN); Li Tian, Haidian District Beijing (CN); Li Zhang, Haidian District Beijing (CN); Huichao Qin, Haidian District Beijing (CN); Ping an Wang, Haidian District Beijing (CN); Wensheng Yin, Haidian District Beijing (CN); Jinchun Hu, Haidian District Beijing (CN); Haihua Mu, Haidian District Beijing (CN)

(21) Appl. No.: 14/651,385

(22) PCT Filed: Dec. 6, 2013
(86) PCT No.: PCT/CN2013/088729

§ 371 Date: Jun. 11, 2015

(30) Foreign Application Priority Data
Dec. 11, 2012 (CN) 201210533774.1

(51) Int. Cl. H01L 21/673

(52) U.S. Cl. CPC H01L 21/67346

(57) ABSTRACT

A silicon wafer platform with anti-collision function comprises a silicon wafer platform body (1) and a cable platform (2). The cable platform (2) is mounted on one side of the silicon wafer platform. The silicon wafer platform comprises three airbags (3), four damping buffer elements (4) and an air source (6), the three airbags (3) being connected in series and respectively secured on the other three sides of the silicon wafer platform by an airbag support (5), two adjacent airbags (3) communicating with a gas pipeline by one damping buffer element (4), and the gas pipeline being secured on the cable platform (2) and communicating with the air source. When two silicon platforms collide, the collision is buffered by the airbags and the silicon wafer platforms are not bounced off.

### TECHNICAL FIELD

The present invention relates to a dual wafer stage switching system for a lithography machine, which can be applied into the lithography machine for semiconductor and belongs to the field of semiconductor manufacturing device.

### BACKGROUND ART

In the magnetic suspending dual wafer stage switching system for a lithography machine, since the two wafer stages have no handspike or other limit structure, controlling the positions and postures of the wafer stages on the balancing block is completely depending on the position measurement by the sensors. Besides, when the two stages are exchanging or the controlling system fails, the two stages may collide, causing great damage and cost to themselves due to their complicated structures. Therefore, an anti-collision structure is crucial for wafer stages. Further, when the two stages collide, they may bounce off from each other, in which case, the measuring system cannot operate before performing direction finding and zero-setting, which has a great negative influence on the efficiency of production. Therefore, a stable buffer structure is necessary for the anti-collision system so as to promptly stop the moving stages when collision occurs.

In prior art, the anti-collision structure is a structure in which cantilever bars amounted along the two sides of the wafer stage with sensors disposed on the cantilever bars. When the two stages are getting too close, the sensors send an alarming signal in response to which the moving stages stop promptly. However, if the controlling system fails, the cantilever bar, and then the stages, are collided and damaged, without any secondary protection. As to the design, if the wafer stages are added at their peripheral with the anti-collision bars, proximity sensors and buffers etc., the stages may have an overly large size, and besides, for the device which has a higher requirement for the integration level, the complicatedness of the structure and the difficulty of design will be increased when adding a plurality of elements, parts and sensors thereto.

### SUMMARY OF THE INVENTION

The present invention provides a wafer stage having function of anti-collision, using gasbags and buffer elements as anti-collision structures, which has the following advantages: (i) when the two wafer stages are being exchanged or the controlling system fails, the parts of the wafer stages can be protected and the measuring system can operate normally, thus improve the efficiency of production; (ii) the stage has a simple structure which facilitates maintenance work.

A wafer stage having function of anti-collision is provided, comprising a body and a cable stage fixed on one side of the body, wherein: the wafer stage further includes three gasbags, four damping buffer elements and a gas source, the three gasbags are arranged in series and are fixed on the other three sides of the body respectively by a gasbag support; adjacent two gasbags have a damping buffer element therebetween to be in communication with a gas conduit which is fixed on the cable stage and in communication with the gas source.

Further, the damping buffer element has at least one long slim damping hole thereon.

Further, the gasbag is made of rubber.

In comparison with the prior art, the present invention has the following advantages: since the gasbags made of rubber have good elasticity, when collision occurs, the gas is squeezed, into adjacent two gasbags via the damping buffer element (i.e., the damping hole), and then into the gas circulation system. Therefore, the damping hole can locally change the flow area of the fluid to generate a pressure loss, achieving purposes such as throttling, pressure regulating, buffering, and anti-vibration. In the present invention, the damping hole has a simple structure of long slim hole. When the damping buffer element is in a state of stable laminar flow, the pressure difference between two ends of the damping buffer element is in a good proportional relation with the flow rate through the damping hole, which can effectively increase the damping force and buffer the bouncing force on collision in a maximized way, thus stopping the moving wafer stages promptly when collision occurs. Through the settings for the gas pressure of the gasbags and the parameters of the damping holes, the positioning precision for the two wafer stages can satisfy the requirements of the controlling system, thus the efficiency of production is improved since no zero setting is needed when collision occurs.

### BRIEF DESCRIPTION OF THE DRAWINGS

FIG. 1 illustrates the structure and principle of the wafer stage having function of anti-collision according to embodiments of the present invention;

FIG. 2 illustrates one operating state of the two wafer stages having function of anti-collision according to the embodiments of the present invention when collision occurs between them; and

FIG. 3 illustrates another operating state of the two wafer stages having function of anti-collision according to the embodiments of the present invention when collision occurs between them.

In the Figures, 1—body of the wafer stage; 2—cable stage; 3—gasbag; 4—damping buffer element; 5—gasbag support; 6—gas source; 7—base; 8a—the first wafer stage; 8b—the second wafer stage.

### DETAILED DESCRIPTION OF THE EMBODIMENTS

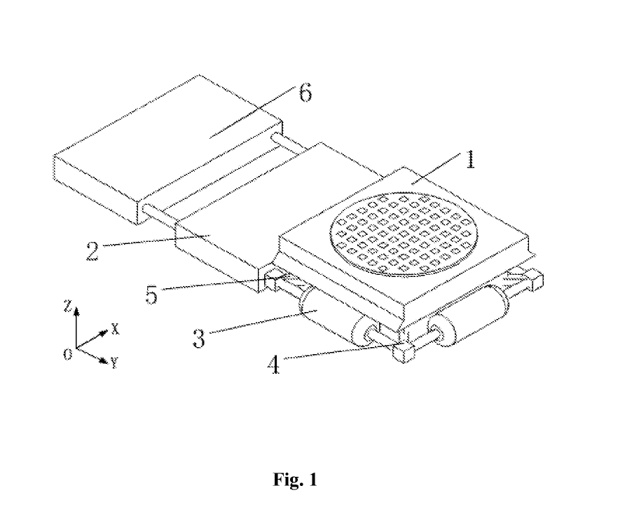

FIG. 1 illustrates the structure and principle of the wafer stage having function of anti-collision according to embodiments of the present invention. The wafer stage includes a body 1 and a cable stage 2 fixed on one side of the body. The wafer stage further includes three gasbags 3, four damping buffer elements 4 and a gas source 6. The gasbags are made of rubber. The three gasbags are arranged in series and are fixed on the other three sides of the body by an airbag support 5. Adjacent two gasbags have a damping buffer element therebetween to be in communication with a gas conduit which is fixed on the cable stage and in communication with the gas source 6. Each of the damping buffer elements preferably includes a plurality of long slim damping holes for throttling, which can locally change the flow area of the gas flow to generate a pressure loss, achieving purposes such as throttling, pressure regulating, buffering and anti-vibration, especially the long slim dampling hole which has a length/diameter ratio (L/D ratio) of more than 10 can have a good buffering performance. The long slim damping hole has a simple structure. When it is in a state of stable laminar flow, the pressure difference between the two ends of the damping buffer element is in a good proportional relation with the flow rate through the damping hole.

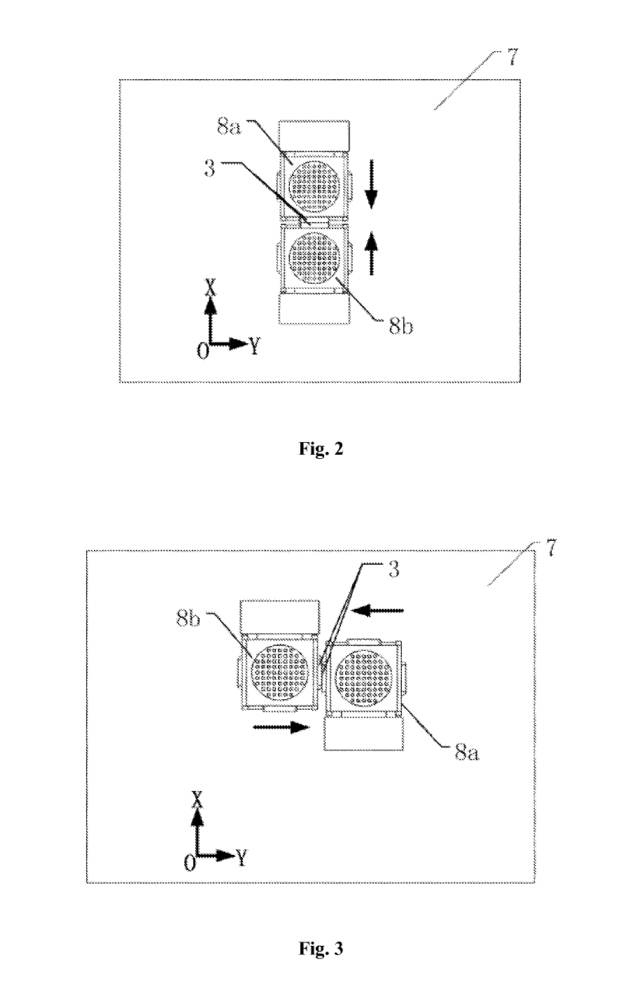

FIG. 2 illustrates one operating state of the two wafer stages having function of anti-collision according to the embodiments of the present invention when collision occurs between them. When a first wafer stage 8a and a second wafer stage 8b are moving along an X direction and collide each other, the first wafer stage 8a moving along the X direction is moving towards the second wafer stage 8b operating normally, and then, gasbags disposed along an Y direction of the anti-collision gasbags of the two wafer stages, first contact with each other. When the gasbags made of rubber are squeezed, the elastic gasbags can deform to buffer the impact force from the collision. Meanwhile, due to the impact force squeezing the internal gas in the two gasbags, a pressure difference is formed between the two collided gasbags and adjacent gasbags connected thereto. At this time, the internal gas in the two collided gasbags can flow to their adjacent gasbags connected thereto via the long slim damping holes disposed at two sides thereof. However, the gas flow during the depressurization is slow, such that the collided gas bags can still have certain degree of rigidity, and the extra gas can be recollected at an outlet of the gas conduit.

The speed of depressurization of the long slim damping hole can be optimized through calculation of the value of the impact force, the parameters relating to the material of the gasbags, and the instantaneous speeds on collision etc., in such a manner that the two moving wafer stages can be stopped promptly on colliding due to the elasticity of the gasbags and the wafer stages will not bounce back due to a certain degree of rigidity of the gasbags. Through the above process, a double anti-collision protection can be achieved for the two wafer stages.

FIG. 3 illustrates another operating state of the two wafer stages having function of anti-collision when collision occurs between them. When the first wafer stage 8a and the second wafer stage 8b are moving along the Y direction and collide with each other, the first wafer stage 8a moving along the Y direction is moving towards the second wafer stage 8b operating normally, and then, the two gasbags disposed along the X direction of the anti-collision gasbags of the two wafer stages, first contact each other. When the gasbags made of rubber are squeezed, the elastic gasbags can deform to buffer the impact force from the collision. Meanwhile, due to the impact force squeezing the internal gas in the two gasbags, a pressure difference is formed between the two collided gasbags and adjacent gasbags connected thereto, at this time, the internal gas in the two collided gasbags can flow to their adjacent gasbags connected thereto via the long slim damping holes disposed at two sides thereof. However, the gas flow during the depressurization is slow, such that the collided gas bags can still have a certain degree of rigidity, and the extra gas can be recollected at an outlet of the gas conduit.

1. A wafer stage having function of anti-collision, comprising a body (1) having four sides and a cable stage (2) mounted on one side of the body,
wherein the wafer stage further comprises three gasbags (3), four damping buffer elements (4) and a gas source (6), the three gasbags are arranged in series and are fixed on the other three sides of the body by a gasbag support (5), and adjacent two gasbags have a damping buffer element (4) therebetween to be in communication with a gas conduit which is in communication with the gas source (6) and fixed on the cable stage.

2. The wafer stage according to claim 1, wherein the damping buffer element defines at least one long slim damping hole.

3. The wafer stage according to claim 1, wherein the gasbag is made of rubber.

4. The wafer stage according to claim 2, wherein the gasbag is made of rubber.
